(19) United States
(12) Patent Application Publication
(10) Pub. No.: US 2007/0252174 A1
(43) Pub. Date: Nov. 1, 2007

(54) Method of manufacturing semiconductor device and semiconductor device

(75) Inventors: Shigeharu Yamagami, Yokohama-shi (JP); Masakatsu Hoshi, Yokohama-shi (JP); Yoshio Shimoida, Yokosuka-shi (JP); Tetsuya Hayashi, Yokosuka-shi (JP); Hideaki Tanaka, Yokohama-shi (JP)

Correspondence Address: FOLEY AND LARDNER LLP;SUITE 500, 3000 K STREET NW, WASHINGTON, DC, 20007, US

(73) Assignee: NISSAN MOTOR CO., LTD.

(21) Appl. No.: 11/790,380

(22) Filed: Apr. 25, 2007

(30) Foreign Application Priority Data
Apr. 28, 2006 (JP) 2006-125160

(51) Int. Cl. H01L 31/00

(52) U.S. Cl. 257/197

(57) ABSTRACT

After a polycrystalline silicon as a hetero-semiconductor region forming a heterojunction with a semiconductor base is formed on an epitaxial layer configuring the semiconductor base, the unevenness on the surface of the polycrystalline silicon is planarized before a gate insulating film is formed. Alternatively, as the hetero-semiconductor region, amorphous or microcrystal hetero-semiconductor of which crystal grain diameter is small is used. When an amorphous or microcrystal hetero-semiconductor is deposited as the hetero-semiconductor region, a recrystallization annealing process of transforming into the polycrystalline silicon can be applied after the deposition. As a material of the semiconductor base, silicon carbide, gallium nitride or diamond can be used. As a material of the hetero-semiconductor region, silicon, silicon germanium, germanium, or gallium arsenide can be used.

### BACKGROUND OF THE INVENTION

1. Field of the Invention

The present invention relates to a method of manufacturing a semiconductor device and a semiconductor device.

2. Description of the Related Art

A conventional technique as the background of the present invention includes a technique described in Japanese Patent Application Laid-open No. 2003-318413, “High Breakdown Voltage Silicon Carbide Diode and Manufacturing Method Therefor” (hereinafter, Patent Document 1), which is a patent application of the present inventor(s).

In the conventional technique described in the Patent Document 1, on a first principal surface of a semiconductor base in which an N⁻-type silicon carbide epitaxial layer is formed on an N⁺-type silicon carbide substrate, an N⁻-type polycrystalline silicon region and an N⁺-type polycrystalline silicon region having the same conductivity type as and band gaps different from that of the semiconductor base are formed in a contacting manner. The N⁻-type silicon carbide epitaxial layer, and the N⁻-type polycrystalline silicon region and N⁺-type polycrystalline silicon region form a heterojunction. Symbols of + (plus) and − (minus) represent high and low of an introduced impurity density, respectively.

On the N⁻-type silicon carbide epitaxial layer, and the N⁻-type polycrystalline silicon region and the N⁺-type polycrystalline silicon region, a gate insulating film is formed. Adjacent to a junction portion between the N⁻-type silicon carbide epitaxial layer and the N⁺-type polycrystalline silicon region, a gate electrode is formed via the gate insulating film. The N⁻-type polycrystalline silicon region is connected to a source electrode, and on the bottom surface of the N⁺-type silicon carbide substrate, a drain electrode is formed.

In the semiconductor device of the conventional technique thus configured, the source electrode is grounded and a predetermined positive electric potential is applied to the drain electrode. With this state, an electric potential of the gate electrode is controlled, and thus, the semiconductor device functions as a switch.

That is, when the gate electrode is grounded, a reverse bias is applied to a heterojunction between the N⁻-type polycrystalline silicon region and the N⁺-type polycrystalline silicon region, and an N⁻-type silicon carbide epitaxial region, and thus no currents are passed between the drain electrode and the source electrode.

On the other hand, when a predetermined positive voltage is applied to the gate electrode, a gate electric field acts at a heterojunction interface between the N⁺-type polycrystalline silicon region and the N⁻-type silicon carbide epitaxial region. Thus, the thickness of an energetic barrier at the heterojunction interface in contact with the gate insulating film is thinned. As a result, the electric currents are passed between the drain electrode and the source electrode.

In the semiconductor device of such a conventional technique, since the heterojunction portion is used as a control channel for cutting-off or conducting electric currents, a channel length is determined by the degree of the thickness of a heterobarrier. Thus, a conductive characteristic of a low on-resistance is obtained.

In such a conventional technique, when the N⁻-type polycrystalline silicon region and the N⁺-type polycrystalline silicon region are deposited on the first principal surface of the semiconductor base to configure a hetero-semiconductor region, if the deposition is performed by using a general polycrystalline-silicon deposition temperature, unevenness of about 1000 Å occurs on a polycrystalline silicon surface. In the conventional technique, one portion of the hetero-semiconductor region formed with such unevenness on the surface is etched to expose one portion of the surface of the N⁻-type silicon carbide epitaxial layer. With this state, on the N⁻-type silicon carbide epitaxial layer and the hetero-semiconductor region, a gate insulating film of about 1000 Å in film thickness is then deposited, and in addition, a gate electrode material is deposited on the gate insulating film.

### SUMMARY OF THE INVENTION

However, on the surface of the hetero-semiconductor region, the unevenness of about 1000 Å is present as described above. Thus, the gate insulating film also results in being formed with a large unevenness. When the unevenness occurs on the gate insulating film, some portions of the insulating film are thin, or an electric field concentration is generated in some portion. Thus, it is probable that the reliability of the gate insulating film is deteriorated.

When the hetero-semiconductor region is dry-etched, an amount of dry etching becomes ununiform due to the presence of the unevenness on the surface. Thus, it is probable that a damage of the dry etching is locally inflicted on the surface of the silicon carbide semiconductor base in contact with the hetero-semiconductor region. When the etching damage is inflicted on the surface of the silicon carbide semiconductor base, an interface state at a MOS interface, that is, the heterojunction interface, is caused. Thereby, a leak current of the gate insulating film increases, deteriorating the current drive capability of the device.

The present invention has been achieved in view of the circumstances, and an object the invention is to provide a method of manufacturing a semiconductor device having a high current drive capability, in which a film thickness of a gate insulating film can be uniformly formed by planarizing the surface of a hetero-semiconductor region thereby to improve the reliability of the gate insulating film. Another object of the invention is to provide a semiconductor device thereof.

To solve the above problems, according to the present invention, the surface of the hetero-semiconductor region where a gate insulating film contacts is planarized.

### BRIEF DESCRIPTION OF THE DRAWINGS

Exemplary embodiments of the invention will become more fully apparent from the following description and appended claims, taken in conjunction with the accompanying drawings. Understanding that these drawings depict only exemplary embodiments and are, therefore, not to be considered limiting of the invention's scope, the exemplary embodiments of the invention will be described with additional specificity and detail through use of the accompanying drawings in which:

FIG. 1 is a sectional structural view of an element portion for explaining a first process of a method of manufacturing a semiconductor device according to a first embodiment of the present invention;

FIG. 2 is a sectional structural view of an element portion for explaining a second process of the method of manufacturing a semiconductor device according to the first embodiment;

FIG. 3 is a sectional structural view of an element portion for explaining a third process of the method of manufacturing a semiconductor device according to the first embodiment;

FIG. 4 is a perspective view showing a surface AFM image before a surface of an N⁺-type polycrystalline silicon is planarized;

FIG. 5 is a perspective view showing a surface AFM image after the surface of the N⁺-type polycrystalline silicon is planarized by dry etching;

FIG. 6 is a sectional structural view of an element portion for explaining a fourth process of the method of manufacturing a semiconductor device according to the first embodiment;

FIG. 7 is a sectional structural view of an element portion for explaining a fifth process of the method of manufacturing a semiconductor device according to the first embodiment;

FIG. 8 is a sectional structural view of an element portion for explaining a sixth process of the method of manufacturing a semiconductor device according to the first embodiment;

FIG. 9 is a sectional structural view of an element portion for explaining a seventh process of the method of manufacturing a semiconductor device according to the first embodiment;

FIG. 10 is a sectional structural view of an element portion for explaining a first process of a method of manufacturing a semiconductor device according to a second embodiment of the present invention;

FIG. 11 is a sectional structural view of an element portion for explaining a second process of the method of manufacturing a semiconductor device according to the second embodiment;

FIG. 12 is a sectional structural view of an element portion for explaining a first process of a method of manufacturing a semiconductor device according to a third embodiment of the present invention;

FIG. 13 is a sectional structural view of an element portion for explaining a second process of the method of manufacturing a semiconductor device according to the third embodiment;

FIG. 14 is a sectional structural view of an element portion for explaining a third process of the method of manufacturing a semiconductor device according to the third embodiment; and

FIG. 15 is a sectional structural view of an element portion of a semiconductor device manufactured by a conventional manufacturing method.

### DETAILED DESCRIPTION OF THE PREFERRED EMBODIMENTS

Preferred embodiments of a method of manufacturing a semiconductor device according to the present invention will be described below in detail with reference to the accompanying drawings.

### First Embodiment

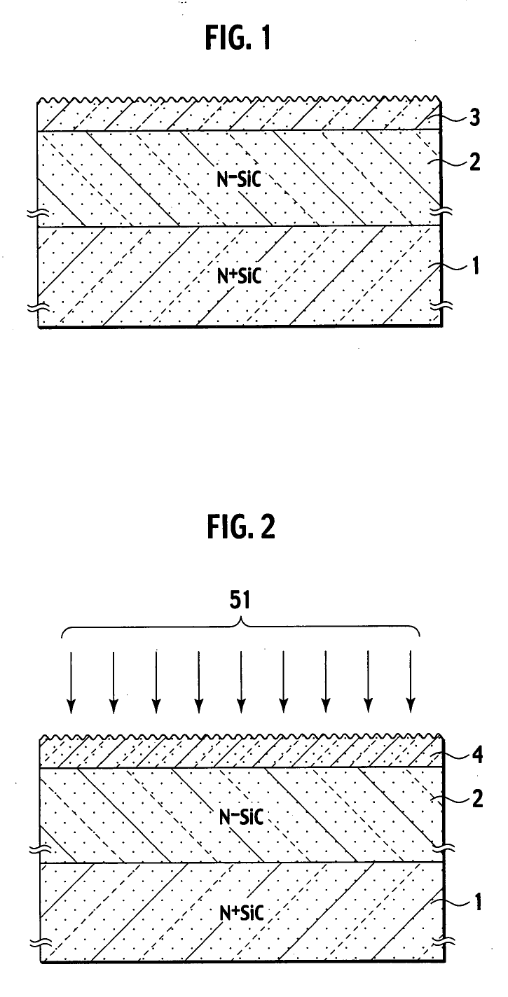

A first embodiment of the present invention is explained with reference to cross-sectional views of FIG. 1 to FIG. 9, in which a manufacturing process is shown. FIG. 1 to FIG. 9 are sectional structural views of an element portion for respectively explaining first to ninth processes of a method of manufacturing a semiconductor device according to the first embodiment.

Firstly, in the first process shown in FIG. 1 (a semiconductor base forming process, a hetero-semiconductor region forming process), on an N⁺-type silicon carbide substrate 1, an N⁺-type silicon carbide epitaxial layer 2 of which impurity concentration is 10¹⁴ to 10¹⁸ cm⁻³ and thickness is 1 to 100 μm is formed to fabricate a semiconductor base. Thereafter, on the N⁺type silicon carbide epitaxial layer 2 configuring the semiconductor base, polycrystalline silicon 3 is deposited with a thickness of 0.1 to 10 μm, for example. The polycrystalline silicon 3 is a semiconductor material having a band gap different from that of the N⁻-type silicon carbide epitaxial layer 2 of the semiconductor base, and forms a hetero-semiconductor region forming a heterojunction with the N⁻-type silicon carbide epitaxial layer 2.

In the second process (a hetero-semiconductor region impurity introducing process) shown in FIG. 2, ions of N-type impurities 51 of which conductivity type is the same as that of the semiconductor base are implanted into the polycrystalline silicon 3 to form high-density N⁺-type polycrystalline silicon 4. Examples of the N-type impurities 51 include arsenic, and phosphorus. Impurity introducing methods can include, in addition to the ion implantation, a method for introducing phosphorous or the like during the deposition of the polycrystalline silicon, and a method in which a heavily-doped deposition film is deposited on the polycrystalline silicon 3, and by using a thermal treatment at 600 to 1000° C., the impurities in the deposition film are directly introduced in the polycrystalline silicon 3.

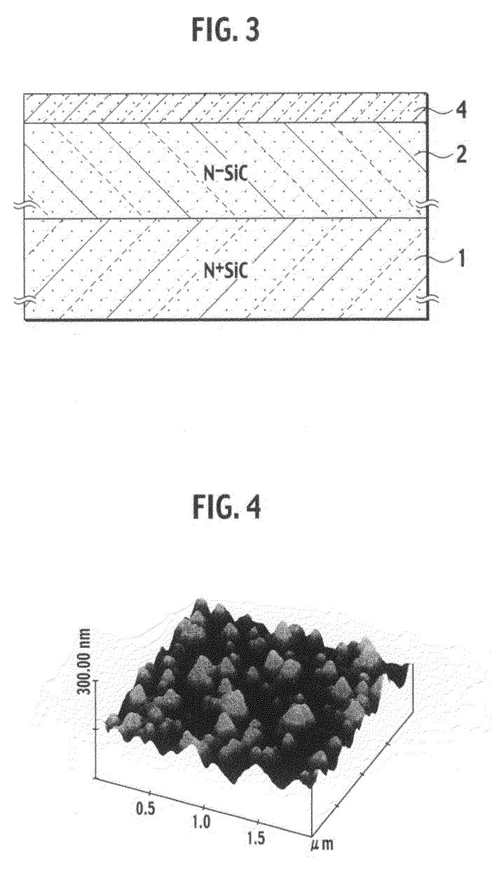

In the third process (a hetero-semiconductor region planarization process) shown in FIG. 3, the surface of the N⁺-type polycrystalline silicon 4 is planarized. Before the hetero-semiconductor region planarization process is performed, the surface of the N⁺-type polycrystalline silicon 4 generally has a large unevenness for a maximum of 1240 Å as shown in an AFM image (Atom Force Microscopy Image) in FIG. 4. The uneven surface of the N⁺-type polycrystalline silicon 4 is dry-etched, for example, so that the surface is planarized to at least 600 Å or less. As a result, as shown in an AFM image in FIG. 5, for example, an uneven value of the surface of the N⁺-type polycrystalline silicon 4 can be reduced to half or less, or to 560 Å at a maximum. FIG. 4 is a perspective view showing a surface AFM image before the surface of the N⁺-type polycrystalline silicon 4 is planarized. FIG. 5 is a perspective view showing a surface AFM image after the surface of the N⁺-type polycrystalline silicon 4 is planarized by the dry etching.

In the hetero-semiconductor region planarization process according to the present embodiment, a case where the dry etching is used is shown as a method for planarizing the surface of the N⁺-type polycrystalline silicon 4. However, a planarization process such as wet etching, and CMP (Chemical Mechanical Polishing) can be used to planarize the surface of the N⁺-type polycrystalline silicon 4.

In the present embodiment, as shown in the second process (the hetero-semiconductor region impurity introducing process) shown in FIG. 2, an example in which the ion implantation of the N-type impurities 51 is performed immediately after the polycrystalline silicon 3 is deposited in the first process in FIG. 1 is shown. However, to form the N⁺-type polycrystalline silicon 4, the ion implantation of the N-type impurities 51 can be performed after the planarization of the polycrystalline silicon 3.

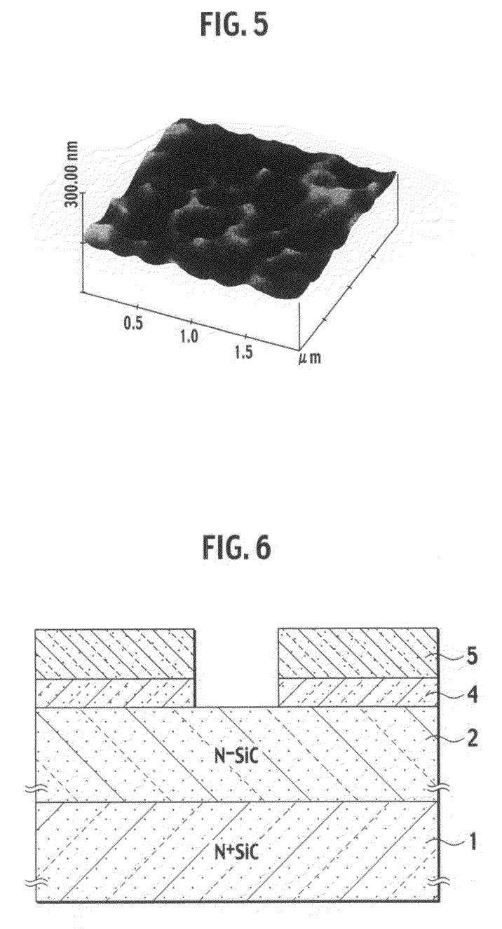

In the subsequent fourth process (a hetero-semiconductor region patterning process) shown in FIG. 6, a resist 5 is formed in a previously determined region on the N⁺-type polycrystalline silicon 4, and the N⁺-type polycrystalline silicon 4 is dry-etched by using the resist 5 as a mask to pattern the N⁺-type polycrystalline silicon 4. At this time, to prevent occurrence of a damage of the dry etching inflicted on the N⁻-type silicon carbide epitaxial layer 2 of the silicon carbide semiconductor base, it is possible to use a process in which an amount by which the N⁺-type polycrystalline silicon 4 is dry-etched is adjusted such that the N⁺-type polycrystalline silicon 4 remains thinly on the N⁻-type silicon carbide epitaxial layer 2, and the remainder of the N⁺-type polycrystalline silicon 4 is removed by sacrifice oxidation and oxide film wet etching to expose the N⁻-type silicon carbide epitaxial layer 2.

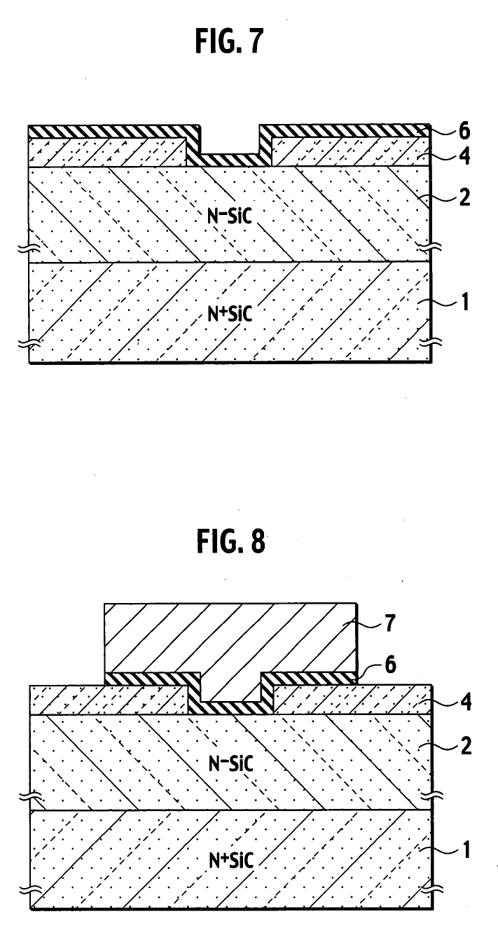

In the subsequent fifth process (a gate insulating film forming process) shown in FIG. 7, on the N⁺-type polycrystalline silicon 4 and the exposed N⁻-type silicon carbide epitaxial layer 2, a CVD oxide film is deposited, for example, to form a gate insulating film 6. Since the surface of the N⁺-type polycrystalline silicon 4 has been planarized by undergoing the third process shown in FIG. 3, it is also possible to form the gate insulating film 6 with a planarized and uniform film thickness.

In the sixth process (a gate electrode forming process) shown in FIG. 8, a gate electrode material is deposited on the gate insulating film 6, and thereafter, a resist pattern is formed by photolithography. The resist pattern is transcribed by dry etching to form a gate electrode 7. Examples of the gate electrode material include polycrystalline silicon and metal.

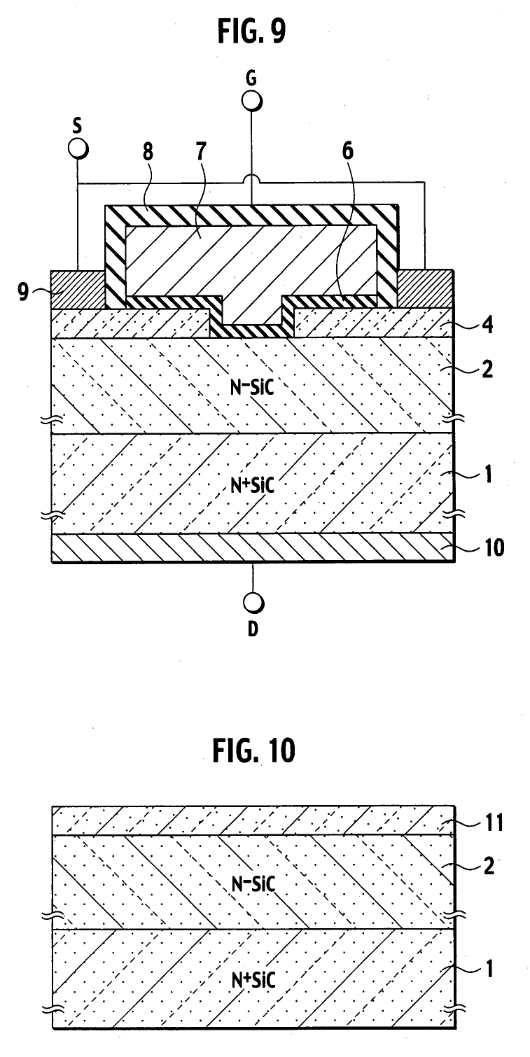

In the last seventh process (a source electrode forming process and a drain electrode forming process) shown in FIG. 9, an interlayer dielectric 8 is firstly formed, and, a contact hole is then opened in the interlayer dielectric 8. Thereafter, a source electrode 9 in ohmic contact with the N⁺-type polycrystalline silicon 4 is formed. Further, a drain electrode 10 in ohmic contact with the N⁺-type silicon carbide substrate 1 is formed.

In the present embodiment, as explained above, after the polycrystalline silicon 3 is deposited, the planarization treatment, such as dry etching, wet etching, and CMP, is performed on the surface of the polycrystalline silicon 3 or the N⁺-type polycrystalline silicon 4 to achieve the planarization.

This process permits improvement of the film thickness uniformity of the gate insulating film 6 formed on the N⁺-type polycrystalline silicon 4. As a result, an electric field concentration is relaxed, and thus, the reliability of the gate insulating film 6 is improved. Accordingly, a semiconductor device capable of suppressing a leak current of the gate insulating film 6 and having a high current drive capability can be obtained.

The planarization of the surface of the N⁺-type polycrystalline silicon 4 can improve the uniformity of an amount of the dry etching performed to pattern the N⁺-type polycrystalline silicon 4. Thus, it becomes possible to surely decrease the probability that the etching damage is locally inflicted on the N⁻-type silicon carbide epitaxial layer 2 configuring the semiconductor base. As a result, it becomes possible to prevent the occurrence of an interface state at a MOS interface, that is, a heterojunction interface. Thereby, a semiconductor device having a superior current drive capability can be obtained.

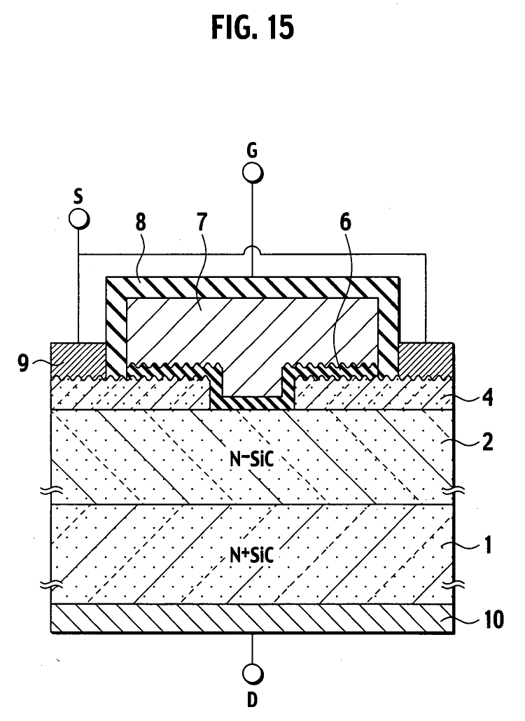

In a semiconductor device manufactured by a conventional manufacturing method that does not include a process of planarizing the surface of the polycrystalline silicon 3 or the N⁺-type polycrystalline silicon 4, which corresponds to the third process (the hetero-semiconductor region planarization process) shown in FIG. 3, the unevenness on the surface of the N⁺-type polycrystalline silicon 4 locally becomes large and exceed 1000 Å (that is almost equal to the film thickness of the gate insulating film 6), as shown in FIG. 15. As a result, the unevenness of the gate insulating film 6 is large, and the uniformity of the film thickness cannot be obtained, either.

### Second Embodiment

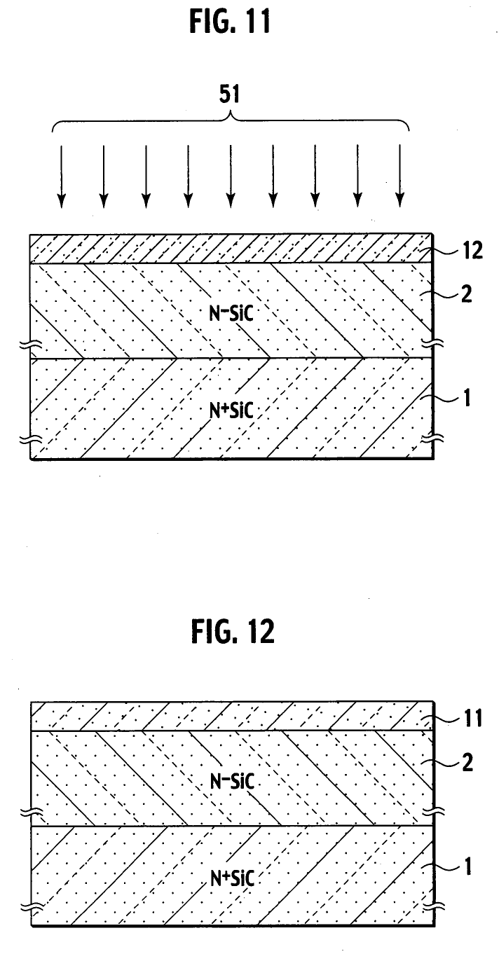

A second embodiment of the present invention is explained next based on cross-sections in FIGS. 10 and 11, in which a manufacturing process is shown. In the present embodiment, there is shown a case that unlike the first embodiment, as a semiconductor material from which the hetero-semiconductor region is formed, a material of which surface has a small roughness is used, and thus, even when a process of planarizing the surface of the hetero-semiconductor region is not provided, the unevenness of the surface can be suppressed to 600 Å or less. FIG. 10 and FIG. 11 are sectional structural views of an element portion for explaining first and second processes of a method of manufacturing a semiconductor device according to the second embodiment. Processes from the second process shown in FIG. 11 onward are the same as those of the fourth to seventh processes shown in FIG. 6 to FIG. 9 according to the first embodiment.

Firstly, in the first process (a semiconductor base forming process, and an amorphous or microcrystal region forming process) shown in FIG. 10, similar to the first embodiment, on the N⁺-type silicon carbide substrate 1, the N⁻-type silicon carbide epitaxial layer 2 of which impurity concentration is 10¹⁴ to 10¹⁸ cm⁻³ and thickness is 1 to 100 μm is formed to fabricate a semiconductor base. Subsequently, on the N⁻type silicon carbide epitaxial layer 2 configuring the semiconductor base, amorphous silicon or microcrystal silicon 11, unlike the first embodiment, is deposited with a thickness of 0.1 to 10 μm, for example, as an amorphous or microcrystal region that results in the hetero-semiconductor region. The amorphous silicon or microcrystal silicon 11 deposited as the amorphous or microcrystal region is a semiconductor material having a band gap different from that of the N⁻-type silicon carbide epitaxial layer 2 of the semiconductor base, and forms a hetero-semiconductor region forming a heterojunction with the N⁻-type silicon carbide epitaxial layer 2.

The amorphous silicon or microcrystal silicon 11 forming the hetero-semiconductor region has a crystal grain diameter smaller than that of the polycrystalline silicon 3 according to the first embodiment. Thus, the unevenness on the surface of the hetero-semiconductor region can be suppressed to a small value, that is, 600 Å or less.

In the second process (a hetero-semiconductor region impurity introducing process) shown in FIG. 11, ions of the N-type impurities 51 of which conductivity type is the same as that of the semiconductor base are implanted into the amorphous silicon or microcrystal silicon 11 to form high-density N⁺-type amorphous silicon or N⁺-type microcrystal silicon 12. Examples of the N-type impurities 51 include arsenic, and phosphorus. Examples of methods of introducing impurities include, in addition to the ion implantation, a method of introducing phosphorus or the like during the deposition of the amorphous silicon or microcrystal silicon.

The processes from the second process shown in FIG. 11 onward are, as explained above, the same processes as the fourth to seventh processes shown in FIG. 6 to FIG. 9 according to the first embodiment. Through these processes, the ultimate semiconductor device can be fabricated.

In the present embodiment, the amorphous or microcrystal silicon having a good surface planarization is deposited as the hetero-semiconductor region to improve the surface planarization of the hetero-semiconductor region. This permits improvement of the film thickness uniformity of the gate insulating film 6 formed on the N⁺-type amorphous silicon or N⁺-type microcrystal silicon 12 of the hetero-semiconductor region. As a result, the electric field concentration is relaxed, and thus, the reliability of the gate insulating film 6 can be improved. Accordingly, a semiconductor device capable of suppressing a leak current of the gate insulating film 6 and having a high current drive capability can be obtained.

The surface of the N⁺-type amorphous silicon or N⁺-type microcrystal silicon 12, as the N⁺-type hetero-semiconductor region, is planarized. Thus, it is possible to improve the uniformity of an amount of dry etching used to pattern the N⁺-type amorphous silicon or N⁺-type microcrystal silicon 12, thereby surely decreasing the locally occurring etching damage inflicted on the N⁻-type silicon carbide epitaxial layer 2 configuring the semiconductor base. As a result, it becomes possible to prevent the occurrence of an interface state at a MOS interface, that is, a heterojunction interface. Thereby, a semiconductor device having a superior current drive capability can be obtained.

### Third Embodiment

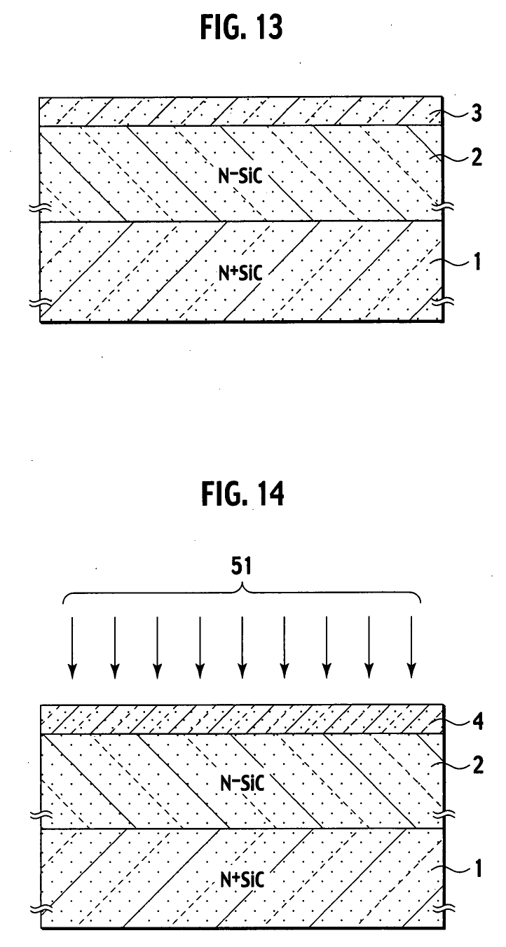

Subsequently, a third embodiment of the present invention is explained based on cross-sections in FIG. 12 to FIG. 14, in which a manufacturing process is shown. In the present embodiment, similar to the second embodiment, the amorphous silicon or microcrystal silicon 11 having a small surface roughness is used as a semiconductor material forming the hetero-semiconductor region. However, in the present embodiment, there is shown a manufacturing method in which the amorphous silicon or microcrystal silicon 11 that has been deposited on the semiconductor base is thermally treated to polycrystallize the amorphous silicon or microcrystal silicon 11, and thus, an on-resistance can be reduced while planarizing the surface of the hetero-semiconductor region. FIG. 12 to FIG. 14 are each sectional structural views of an element portion for explaining first to third processes of a method of manufacturing a semiconductor device according to the third embodiment. Processes from the third process shown in FIG. 14 onward are the same as those of the fourth to seventh processes shown in FIG. 6 to FIG. 9 according to the first embodiment.

Firstly, in the first process (a semiconductor base forming process, and an amorphous or microcrystal region forming process), similar to the second embodiment, the N⁻-type silicon carbide epitaxial layer 2 of which impurity concentration is 10¹⁴ to 10¹⁸ cm⁻³ and thickness is 1 to 100 μm, for example, is formed on the N⁺-type silicon carbide substrate 1 to fabricate the semiconductor base. Subsequently, on the N⁻-type silicon carbide epitaxial layer 2 configuring the semiconductor base, the amorphous silicon or microcrystal silicon 11, as an amorphous or microcrystal region that results in the hetero-semiconductor region, is deposited with a thickness of 0.1 to 10 μm. The amorphous silicon or microcrystal silicon 11 deposited as the amorphous or microcrystal region is a semiconductor material having a band gap different from that of the N⁻-type silicon carbide epitaxial layer 2 of the semiconductor base, and forms a hetero-semiconductor region forming a heterojunction with the N⁻-type silicon carbide epitaxial layer 2.

As explained above, the amorphous silicon or microcrystal silicon 11 forming the hetero-semiconductor region has a crystal grain diameter smaller than that of the polycrystalline silicon 3 in the first embodiment. Thus, the unevenness on the surface of the hetero-semiconductor region can be suppressed to a small value, that is, 600 Å or less.

Subsequently, in the second process (a hetero-semiconductor region polycrystallization process) shown in FIG. 13, as a result of a thermal treatment, that is, a recrystallization annealing (SPC: Solid Phase Crystallization) process, the deposited amorphous silicon or microcrystal silicon 11 is increased in the crystal grain diameter thereby to transform into a polycrystalline silicon 3. Examples of the thermal treatment include a low-temperature long-time thermal treatment for 65 hours at 600° C., a thermal treatment for 20 minutes at 900° C. The thermal treatment improves the mobility of carriers, and decreases a sheet resistance of the deposited amorphous or microcrystal silicon 11. As a result, the on-resistance as a switching device is decreased, and the current drive capability can be improved.

In the subsequent third process (a hetero-semiconductor region impurity introducing process) shown in FIG. 14, ions of the N-type impurities 51 of which conductivity type is the same as that of the semiconductor base are implanted into the polycrystalline silicon 3 in which the amorphous or microcrystal silicon 11 is polycrystallized to form the high-density N⁺-type amorphous silicon 4. Examples of the N-type impurities 51 include arsenic, phosphorus. Examples of methods of introducing impurities include, in addition to the ion implantation, a method of introducing phosphorus or the like during the deposition of the amorphous silicon or microcrystal silicon.

In the present embodiment, as in the third process (the hetero-semiconductor region impurity introducing process) shown in FIG. 14, there has been shown an example in which the ion implantation of the N-type impurities 51 is performed after the thermal treatment for increasing the crystal grain diameter in the second process (the hetero-semiconductor region polycrystalline process) shown in FIG. 13. However, it is possible that immediately after the amorphous or microcrystal silicon 11 is deposited on the N⁻-type silicon carbide epitaxial layer 2 configuring the semiconductor base, the thermal treatment for increasing the crystal grain diameter of the amorphous or microcrystal silicon 11 is performed, and thereafter, the ions of the N-type impurities 51 are implanted to form the N⁺-type polycrystalline silicon 4.

The processes from the third process shown in FIG. 14 onward are, as explained above, the same processes as the fourth to seventh processes shown in FIG. 6 to FIG. 9 according to the first embodiment. Through these processes, the ultimate semiconductor device can be fabricated.

In the present embodiment, after the amorphous or microcrystal silicon 11 having a good surface planarization is deposited on the N⁻-type silicon carbide epitaxial layer 2 as the hetero-semiconductor region, or after the N-type impurities are introduced into the deposited amorphous or microcrystal silicon 11, the crystal grain diameter is increased by the thermal treatment so that the amorphous or microcrystal silicon 11 is transformed into the polycrystalline silicon 3. Thus, it is possible to form the N⁺-type polycrystalline silicon 4 of a low sheet resistance while keeping the surface planarization of the hetero-semiconductor region. As a result, a higher current drive capability can be secured.

This permits improvement of the film thickness uniformity of the gate insulating film 6 formed on the N⁺-type polycrystalline silicon 4. As a result, an electric field concentration is relaxed, and thus, the reliability of the gate insulating film 6 is improved. Accordingly, a semiconductor device capable of suppressing a leak current of the gate insulating film 6 and having a high current drive capability can be obtained.

The surface of the N⁺-type polycrystalline silicon 4 can be formed in a planarizing manner. Thus, the uniformity of an amount of dry etching performed to pattern the N⁺-type polycrystalline silicon 4 can be improved. As a result, the etching damage locally occurring in the N⁻-type silicon carbide epitaxial layer 2 configuring the semiconductor base can be surely reduced. Consequently, it becomes possible to prevent the occurrence of an interface state at a MOS interface, that is, a heterojunction interface. Thereby, a semiconductor device having a superior current drive capability can be obtained.

The embodiments described above show an example in which the silicon carbide is used as the semiconductor base material, and the polycrystalline silicon or amorphous silicon or microcrystal silicon is used as the material of the hetero-semiconductor region. However, the present invention is not limited to these materials, and the material of the semiconductor base can include gallium nitride or diamond, for example.

The material of the hetero-semiconductor region, as long as the material can form the hetero-semiconductor region formed of the semiconductor material having a band gap different from that of the semiconductor base, is not limited to the polycrystalline silicon, the amorphous silicon or the microcrystal silicon. Single crystal silicon or silicon germanium can be used, or germanium or gallium arsenide can be used.

According to the method of manufacturing a semiconductor device and a semiconductor device of the present invention, the surface of a hetero-semiconductor region where the gate insulating film contacts is planarized. Thus, the planarization and the film thickness uniformity of the gate insulating film formed on the surface of the hetero-semiconductor region can be improved. Thus, the reliability of the gate insulating film is improved, and a semiconductor device having a high current drive capability can be provided.

Description has been made of the embodiments to which the invention created by the inventors of the present invention is applied. However, the present invention is not limited to the descriptions and the drawings, which form a part of the disclosure of the present invention according to these embodiments. Specifically, all of other embodiments, examples, operational techniques and the like, which are made by those skilled in the art based on these embodiments, are naturally incorporated in the scope of the present invention. The above is additionally described at the end of this specification.

The entire content of Japanese Patent Application No. TOKUGAN 2006-125160 with a filing date of Apr. 28, 2006 is hereby incorporated by reference.

What is claimed is:

1. A method of manufacturing a semiconductor device, wherein the semiconductor device includes:
a semiconductor base;
a hetero-semiconductor region formed in a predetermined region on a surface of the semiconductor base and formed of a semiconductor material having a band gap different from that of the semiconductor base;
a gate electrode arranged, via a gate insulating film, adjacent to a heterojunction interface between the semiconductor base and the hetero-semiconductor region;
a source electrode connected to the hetero-semiconductor region; and
a drain electrode connected to the semiconductor base, and wherein
the method comprises a hetero-semiconductor region planarization process of planarizing unevenness on a surface of the hetero-semiconductor region formed on the surface of the semiconductor base.

2. A method of manufacturing a semiconductor device, wherein the semiconductor device includes:
a semiconductor base;
a hetero-semiconductor region formed in a predetermined region on a surface of the semiconductor base and formed of a semiconductor material having a band gap different from that of the semiconductor base;
a gate electrode arranged, via a gate insulating film, adjacent to a heterojunction interface between the semiconductor base and the hetero-semiconductor region;
a source electrode connected to the hetero-semiconductor region; and
a drain electrode connected to the semiconductor base, and wherein
the method comprises an amorphous or microcrystal region forming process of forming an amorphous or microcrystal hetero-semiconductor on the surface of the semiconductor base.

3. A method of manufacturing a semiconductor device, wherein the semiconductor device includes:
a semiconductor base;
a hetero-semiconductor region formed in a predetermined region on a surface of the semiconductor base and formed of a semiconductor material having a band gap different from that of the semiconductor base;
a gate electrode arranged, via a gate insulating film, adjacent to a heterojunction interface between the semiconductor base and the hetero-semiconductor region;
a source electrode connected to the hetero-semiconductor region; and
a drain electrode connected to the semiconductor base, and wherein
the method of manufacturing a semiconductor device comprises a hetero-semiconductor region polycrystallization process of polycrystallizing by a thermal treatment an amorphous or microcrystal hetero-semiconductor formed on the surface of the semiconductor base.

4. The method of manufacturing a semiconductor device according to claim 1, wherein in the hetero-semiconductor region planarization process, the unevenness on the surface of the hetero-semiconductor region is planarized by dry etching.

5. The method of manufacturing a semiconductor device according to claim 1, wherein in the hetero-semiconductor region planarization process, the unevenness on the surface of the hetero-semiconductor region is planarized by wet etching.

6. The method of manufacturing a semiconductor device according to claim 1, wherein in the hetero-semiconductor region planarization process, the unevenness on the surface of the hetero-semiconductor region is planarized by CMP (Chemical Mechanical Polishing).

7. The method of manufacturing a semiconductor device according to claim 1, wherein as a material of the semiconductor base, either silicon carbide, gallium nitride, or diamond is used.

8. The method of manufacturing a semiconductor device according to claim 1, wherein as a material of the hetero-semiconductor region, either silicon or silicon germanium is used.

9. The method of manufacturing a semiconductor device according to claim 1, wherein as a material of the hetero-semiconductor region, either germanium or gallium arsenide is used.

10. A semiconductor device, comprising:
a semiconductor base;
a hetero-semiconductor region formed in a predetermined region on a surface of the semiconductor base and formed of a semiconductor material having a band gap different from that of the semiconductor base;
a gate electrode arranged, via a gate insulating film, adjacent to a heterojunction interface between the semiconductor base and the hetero-semiconductor region;
a source electrode connected to the hetero-semiconductor region; and
a drain electrode connected to the semiconductor base, wherein
a surface of a polycrystalline semiconductor region formed as the hetero-semiconductor region is planarized.

11. A semiconductor device, comprising:
a semiconductor base;
a hetero-semiconductor region formed in a predetermined region on a surface of the semiconductor base and formed of a semiconductor material having a band gap different from that of the semiconductor base;
a gate electrode arranged, via a gate insulating film, adjacent to a heterojunction interface between the semiconductor base and the hetero-semiconductor region;
a source electrode connected to the hetero-semiconductor region; and
a drain electrode connected to the semiconductor base, wherein
the hetero-semiconductor region is formed of amorphous or microcrystal hetero-semiconductor.

12. The semiconductor device according to claim 10, wherein a material of the semiconductor base is made of either silicon carbide, gallium nitride, or diamond.

13. The semiconductor device according to claim 10, wherein a material of the hetero-semiconductor region is made of either silicon or silicon germanium.

14. The semiconductor device according to claim 10, wherein a material of the hetero-semiconductor region is made of either germanium or gallium arsenide.
